(19) United States
(12) Patent Application Publication
(10) Pub. No.: US 2008/0206484 A1
(43) Pub. Date: Aug. 28, 2008

(54) Graphitized Carbon Coatings for Composite Electrodes

(75) Inventors: Robert Kostecki, Lafayette, CA (US); Marek Marcinek, Warszawa (PL)

Correspondence Address: LAWRENCE BERKELEY NATIONAL LABORATORY, ONE CYCLOTRON ROAD, MAIL STOP 90B, UNIVERSITY OF CALIFORNIA, BERKELEY, CA, 94720, US

(73) Assignee: THE REGENTS OF THE UNIVERSITY OF CALIFORNIA

(21) Appl. No.: 11/915,837

(22) PCT Filed: May 31, 2006
(86) PCT No.: PCT/US2006/021203

§ 371 Date: Nov. 28, 2007

Related U.S. Application Data
(60) Provisional application No. 60/686,339, filed on May 31, 2005.

(51) Int. Cl. C23C 16/26; C23C 16/44; C23C 16/28

(52) U.S. Cl. 427/575; 427/595

(57) ABSTRACT

A method for forming a graphitic carbon film at low temperatures is described. The method involves using microwave radiation to produce a neutral gas plasma in a reactor cell. At least one carbon precursor material in the reactor cell forms a graphitic carbon film on a substrate in the cell under influence of the plasma. This method can be used to coat active electrode material powders with highly conductive carbon, which can be especially useful in forming composite electrodes. When an organometallic is used as the precursor, this method can also be used to form carbon/metal catalyst films.

### CROSS-REFERENCE TO RELATED APPLICATIONS

This application is a national phase application of PCT International Application PCT/US2006/021203, filed May 31, 2006, which claims priority to U.S. Patent Provisional Application 60/686,339, filed May 31, 2005, both of which are incorporated by reference herein.

### STATEMENT OF GOVERNMENTAL SUPPORT

The invention described and claimed herein was made in part utilizing funds supplied by the U.S. Department of Energy under Contract No. DE-AC03-76SF00098, and more recently under DE-AC02-05CH11231. The government has certain rights in this invention.

### TECHNICAL FIELD

This invention relates generally to methods of producing highly conductive carbon, and, more specifically, to methods of coating active electrode material particles with highly conductive carbon.

### BACKGROUND ART

When carbon films are produced by pyrolysis of organic precursors, as is well known in the art, the electronic conductivity of the carbon films depends strongly on the pyrolysis temperature. FIG. 1 shows a graph of resistance as a function of pyrolysis itemperature for thin films of pyrolized photoresist. Resistance was measured by a four point probe method. There is a difference in conductivity of several orders of magnitude between pyrolytic carbon films produced at 600° C. and those produced at 800° C.

It has been found that the structure of carbon films produced by simple pyrolysis of organic precursors also varies with the temperature of pyrolysis. To form graphitic carbon films, it is necessary to use temperatures above 1800° C. For many applications wherein conductive carbon films are desired, processing at high temperatures is possible. But for other applications wherein, for example, the substrates on which the carbon films are deposited are temperature sensitive, processing at high temperatures can change the properties of the substrates in undesirable ways.

Microwaves have been used in various technological and scientific fields to produce and/or regenerate carbonaceous materials. In microwave heating, energy is transmitted directly to a target material through direct interaction between the microwaves and the molecules of the material. Thus treatment time is fast. Furthermore, the structure of carbonaceous materials that have undergone microwave heating can range from amorphous to highly crystalline, e.g., diamond or graphite. It would be useful to adapt and use microwave technology to produce highly graphitized carbon films with good conductivity and without significant heating of the substrate.

### DISCLOSURE OF INVENTION AND BEST MODE FOR CARRYING OUT THE INVENTION

Some embodiments of the present invention provide a method for utilizing plasma technology and electromagnetic radiation to manufacture conductive carbon films on substrates without need for processing at high temperatures.

According to one embodiment of the invention, microwave plasma-assisted chemical vapor deposition (MPACVD) is used to deposit highly-conductive graphitic carbon films onto substrates at lower temperatures than required for standard pyrolitic deposition of carbon.

In an exemplary embodiment, FIG. 2 shows a cross-section view of a reactor cell 200 that can be used for MPACVD. Other configurations of reactor cell for carrying out the embodiments of the invention are possible and can be designed easily by those having skill in the art. The reactor cell 200 consists of two symmetrical cylindrical segments 210, 220. The cylindrical segments 210, 220 can be made of any material suitable for use in both vacuum and microwave environments. In one arrangement, the cylindrical segments 210, 220 are made of Pyrex™ glass. In another arrangement, the cylindrical segments 210, 220 are made of quartz glass. Each cylindrical segment 210, 220 is fitted with a vacuum valve 212, 222, respectively, at one end and a collar 214, 224, respectively, with an O-ring fitting at the other. To assemble the reactor cell 200, the two collars 214, 224 of the cylindrical segments 210, 220, respectively are pressed onto one another with an O-ring 225 fitted between. The two collars 214, 224 are held tightly together by a rubber clamp (not shown).

Prior to assembling the reactor cell 200, a substrate 230 is placed in one cylindrical segment 210. The substrate 230 can be made of any material suitable for use in vacuum and microwave conditions and on which a conductive carbon film is desired. The substrate 230 can be a continuous solid, solid pieces, or in the form of a powder or granules. Examples of suitable substrates 230 include silicon wafers, glass plates, and battery electrode active material powders (such as LiCoO₂, LiNiO₂, LiNi_{0.8}Cu_{0.2}O₂, LiNi_{0.8}Cu_{0.15}Al_{0.05}O₂, LiFePO₄, and LiNi_{1/3}Co_{1/3}Mn_{1/3}O₂). In one arrangement, an organic precursor (not shown) is introduced into the segment 210 or into the segment 220 and placed in the vicinity of the substrate 230. In another arrangement, an organic precursor is deposited directly onto the substrate 230 in the form of a thin film before the substrate 230 is placed in the cylindrical segment 210. In yet another arrangement, one or more organic precursors are both deposited onto the substrate 230 and placed in the reactor cell 200 near the substrate 230. The reactor cell 200 is assembled by connecting the two segments 210, 220, as described above. The vacuum valve 222 is connected to a neutral gas line 226. The vacuum valve 212 is connected to a vacuum line 216. The reactor cell 200 is flushed with a non-reactive or neutral gas to remove traces of residual gases. In some embodiments, the neutral gas is a noble gas. In one embodiment, the neutral gas is nitrogen. In one arrangement, argon gas flows into the cell 200 at a rate of about 2 scf/hour for about 30 s at ambient pressure. Then the vacuum valve 222 on the neutral gas line 226 is closed and the cell is evacuated through the vacuum line 216 to a base pressure of between about 1 mTorr and 100 mTorr, thus leaving the cell 200 filled with neutral gas at low pressure. The filling and evacuating procedure can be repeated any number of times as desired. When the desired base pressure is achieved, the vacuum valve 212 is closed.

The reactor cell 200 is placed near a microwave generator. In some arrangements, the cell 200 is placed between about 5 mm and 1 m away from the microwave generator. In some arrangements, the cell 200 is placed between about 1 cm and 10 cm away from the microwave generator. The microwave generator is a standard electromagnetic generator capable of providing electromagnetic radiation within the microwave frequency range, i.e., between 300 MHz and 300 GHz. In one arrangement, frequencies between about 500 MHz and 100 GHz are used. In one arrangement, frequencies between about 750 MHz and 10 GHz are used. In one arrangement, frequencies between about 1 GHz and 5 GHz are used. The microwave generator is activated with a power input between about 10 W and 50 kW. In one arrangement, the power input is between about 100 W and 1200 W. In one arrangement, the power input is between about 600 W and 1000 W. The neutral gas in the reactor cell is excited by the microwaves, and a plasma is created. The microwave radiation is continued for between about 1 second and 10 minutes. In one arrangement, the microwave radiation is continued for between about 2 seconds and 1 minute. In another arrangement, the microwave radiation is continued for between about 5 and 15 seconds.

In another embodiment, extra care is taken to exclude oxygen from the reactor cell. If oxygen is available to react with carbon to form CO₂, the efficiency of the carbon deposition process can be diminished. One way to exclude oxygen from the reactor cell 200 is to load and assemble the reactor cell 200 in a glove box (not shown) filled with dry nitrogen. As a further precaution, all reagents and system components can be dried prior to transfer to the glove box.

Interaction of the organic precursor(s) in the cell 200 with the low-pressure plasma and strong electromagnetic microwave radiation initiates an evaporation and pyrolysis process in the gas phase at relatively low temperatures. Plasma pyrolysis of the organic precursor yields uniform films of nanometer-sized carbon particles which precipitate on the substrate and on the walls of the reactor. By adjusting pyrolysis conditions such as gas pressure, microwave radiation power, exposure time, and composition of the organic precursor, highly graphitic carbon films can be produced. The carbon coatings are uniform, exhibit high sp²-graphene crystalline structure, and have excellent electrical conductivity. In one arrangement, the temperature of the substrate goes no higher than 200° C. during the deposition. In another arrangement, the temperature of the substrate goes no higher than 500° C. during the deposition. In yet another arrangement, the temperature of the substrate goes no higher than 800° C. during the deposition.

Uniform graphitic carbon coatings with thicknesses from several tens of nanometers to several tens of micrometers can be formed on the substrate and the walls of the reactor cell using this method. The deposition can be repeated several times to form even thicker films. It is possible to coat solid substrates and both powder and granular substrates with several carbon layers. It can be useful to shake a powder or granular substrate before each carbon deposition in order to expose many portions of each particle to the deposition.

In another embodiment, a reactor cell designed for more continuous deposition of carbon films can be used. In addition to the neutral gas line and vacuum line described above, there can be an additional line into the cell. The additional line can carry carbon precursor materials in the form of gas, liquid or solid (e.g., powder or granules). The carbon precursor line can provide a continuous source of precursor to the process in the cell. In some arrangements, multiple substrates can be loaded into the cell. The positions of the substrates can be controlled from outside the reactor. An individual substrate or group of substrates can be moved into position to receive a carbon film for a period of time. Then the substrate(s) can be moved into a shielded position and new substrate(s) can be moved into position to receive a carbon film. The precursor line can be opened and closed as needed, and the carbon films can be deposited continuously or semi-continuously. A reactor cell of this type can be sized as needed for large-scale manufacturing.

The quality of the MPACVD carbon films, i.e., structure, conductivity and morphology, may vary with the microwave irradiation distribution inside the reactor. When the hot edge of the plasma glow region is near the organic precursor source and the cool edge of the plasma glow region is near the substrate, evaporation of the organic precursor is accelerated and the substrate is less likely to reach a high temperature.

In general, organic precursors that yield CₓH_{y} radicals upon interaction with the microwave-generated plasma are useful for forming carbon films by MPACVD. CₓH_{y} radicals that have an x/y ratio greater than 1 are useful for forming conductive graphite-like carbon coatings. In some embodiments of the invention, organic precursors that have an x/y ratio of about 1 are used. In some embodiments of the invention, organic precursors that have an x/y ratio between about 1 and 2 are used. In some embodiments of the invention, organic precursors that have an x/y ratio between about 2 and 3 are used. For example graphite-like carbon films can be made from solid organic aromatic precursors such as polystyrene, naphtalene and anthracene. In another example, other organic precursors such as sugar, tar etc. can be used for the carbon deposition.

The carbon films were examined by transmission electron microscopy (TEM). The films were found to be highly graphitic, having densely packed nanoparticles with sizes between about 25 nm and 75 nm. Some carbon films have nanoparticles ranging in size between about 30 nm and 50 nm. In some embodiments, the nanoparticles have sized between about 1 nm and 100 nm.

FIG. 3 is a graph showing the current-voltage characteristics, as measured by four-point probe technique, of carbon films made using the methods described herein. The graph indicates that the carbon films have linear, ohmic electronic behavior. Such electronic behavior has been found to be uniform throughout the carbon films.

FIG. 4 shows Raman spectra of four different carbon films made using the methods described herein. All four samples show more intense D and G bands for sp²-coordinated carbon at about 1345 cm⁻¹ and 1580 cm⁻¹ than for sp³-coordinated carbon at about 1480 cm⁻¹. From the Raman data, the measured ratios of sp³ to sp² bonding in the films is between about 0.5 and 0.005. FIG. 5 is a table showing resistivity values as measured for various ratios of sp³ to sp² bonding in carbon films. Sp²-coordinated graphite-like carbon has much lower resistivity and thus much higher electrical conductivity than disordered or sp³-coordinated carbonaceous materials. The greater the proportion of sp² structure, the lower the resistivity and the higher the conductivity. Carbon films, such as those shown in FIG. 4, which have a high proportion of sp²-coordinated carbon, have good electrical conductivity.

To increase the poor electronic conductivity of composite electrodes, a conductive material, such as carbon black and/or graphite, can be mixed in with active electrode material particles. The electrode is then formed by pressing the mixture together. The resulting conductivity of the composite electrode depends on the physico-chemical properties of the active electrode material particles and the added conductive material (e.g., carbon), such as surface areas and surface chemistries of particles, the properties of the interfaces between the particles, density of points of contact, contact area between particles, and intrinsic bulk electronic conductivity of each material in the composite. Thus, it is best to understand and control the chemical composition of the mixture and the processing conditions carefully. To maximize the current density, increase material utilization, and minimize local stress and heating due to inhomogeneities in materials and in electrical transport, carbon particles can be distributed uniformly and can be densely packed along the surfaces of the active electrode material particles to ensure low impedance electrical contacts between the active electrode material particles and the current collector. Low resistance electrical paths between the current collector and the active material contribute to enhanced electrochemical performance of composite electrodes.

In current practice, it is very difficult to control carbon particle arrangement in composite electrodes. In conventional technologies the components of a composite electrode are simply mixed together, yielding non-uniform distribution and poor adherence of carbon additives in the final electrode composite. Consequently, polarization is much higher than if the active electrode material particle surfaces are pre-treated to induce a very uniform distribution of carbon around them. To address these issues, synthesis techniques have been optimized by minimizing active electrode material particle size, improving the conductivity of the active material by doping, adding metal or carbon particles during active electrode material synthesis, reactive ball-milling of active electrode material with carbon, and/or co-synthesis of conductive carbon coatings on the active electrode material particles during pyrolysis of organic additives. Co-pyrolysis at temperatures around 800° C. has produced uniform amorphous carbon films. Even so, this method can be used only with active materials that have sufficient thermal stability at temperatures around 800° C., such as LiFePO₄. There is a difference of several orders of magnitude in conductivity between pyrolytic carbon films produced at 600° C. and those produced at 800° C., i.e., at temperatures where LiFePO₄ synthesis is usually carried out

Thus, one application for which the carbon deposition methods disclosed herein are especially useful is in coating high performance materials for composite electrodes. Conductive carbon additives are commonly used in composite electrodes for Li-ion batteries to increase cycle life and decrease polarization of the electrode. A conductive carbon matrix can provide good electrical contact between non-conductive or poorly conductive particles of active electrode material and current collectors. A low resistance electronic path between the current collector and the active material is essential for good electrochemical performance of composite electrodes, as are used in primary and secondary batteries and for fuel cells. Conductive carbon coatings on particles of the active electrode material are highly advantageous in making good and extensive electronic contact between the surfaces of active material particles and the carbon matrix. When more of the surface areas of the active material particles make good electronic contact to a highly conductive carbon matrix, the overall impedance of the electrode is lower, which translates into higher active material utilization and faster kinetics of the electrochemical processes that occur during the functioning of the electrode. The quality of carbon coating, and thus its conductivity, is particularly important in enhancing utilization and rate capability of composite electrodes. Examples of active electrode materials include LiCoO₂, LiNiO₂, LiNi_{0.8}CO_{0.2}O₂, LiNi_{0.8}CO_{0.15}Al_{0.05}O₂, LiFePO₄, and LiNi_{1/3}Co_{1/3}Mn_{1/3}O₂.

High quality carbon coatings can be deposited onto LiFePO₄ powder or on any other active electrode material powder using the method described above with reference to FIG. 2. One important additional consideration for electrode active materials is that oxygen, especially oxygen plasma, can cause unwanted oxidation of the substrate. Also, oxygen can react with carbon to form CO₂, which can diminish the efficiency of the carbon deposition process. Thus it is useful to reduce the oxygen in the process environment as much as possible. Thus, the reactor cell 200 is loaded in a glove box (not shown) filled with dry nitrogen. All reagents and system components are dried prior to transfer to the glove box. The LiFePO₄ powder substrate 230 is placed in one cylindrical segment 210 of the reaction cell 200. An organic precursor (not shown) is introduced into the cylindrical segment 210 and placed in the vicinity of the substrate 230. The reactor cell 200 is assembled by connecting the two segments 210, 220. The reactor cell 200 is flushed with a non-reactive or neutral gas to remove traces of residual gases. Then the cell 200 is evacuated to a base pressure of between about 1 mTorr and 100 mTorr, leaving the cell 200 filled with a neutral gas at low pressure. The details of these procedures have been described above.

The reactor cell 200 is placed near a microwave generator. In some arrangements, the cell 200 is placed between about 5 mm and 1 m away from the microwave generator. In some arrangements, the cell 200 is placed between about 1 cm and 10 cm away from the microwave generator. The microwave generator is a standard electromagnetic generator capable of providing electromagnetic radiation within the microwave frequency range, i.e., between 300 MHz and 300 GHz. In one arrangement, frequencies between about 500 MHz and 100 GHz are used. In one arrangement, frequencies between about 750 MHz and 10 GHz are used. In one arrangement, frequencies between about 1 GHz and 5 GHz are used. The microwave generator is activated with a power input between about 10 W and 50 kW. In one arrangement, the power input is between about 100 W and 1200 W. In one arrangement, the power input was between about 600 W and 1000 W. The neutral gas in the reactor cell is excited by the microwaves to generate a plasma. The microwave radiation is continued for between about 1 second and 10 minutes. In one arrangement, the microwave radiation is continued for between about 2 seconds and 1 minute. In another arrangement, the microwave radiation is continued for between about 5 and 15 seconds. Interaction of the organic precursor(s) in the cell 200 (either positioned within the cell, as thin films on the substrate, or flowed in through a precursor line) with the low-pressure plasma and strong electromagnetic microwave radiation initiates an evaporation and pyrolysis process in the gas phase at relatively low temperatures. Plasma pyrolysis of the organic precursor yields uniform films of nanometer-sized carbon particles which precipitate on the LiFePO₄ substrate. By adjusting pyrolysis conditions such as gas pressure, microwave radiation power, exposure time, or composition of the organic precursor, highly graphitic carbon films can be produced. The carbon coatings are uniform, exhibit high sp²-graphene crystalline structure, and have excellent electrical conductivity. In one arrangement, the temperature of the LiFePO₄ substrate goes no higher than 200° C. during the deposition. In another arrangement, the temperature of the LiFePO₄ substrate goes no higher than 500° C. during the deposition. In yet another arrangement, the temperature of the LiFePO₄ substrate goes no higher than 800° C. during the deposition.

The deposition can be repeated several times to form films that fully coat the LiFePO₄ particles. The reactor cell is shaken before each deposition to move the powder substrate particles for more complete exposure. Uniform graphitic carbon coatings with thicknesses from several tens of nanometers to several tens of micrometers can be formed on the LiFePO₄ substrate particles using this method. After the deposition the carbon-coated substrate particles from the reactor cell and the particles can be pressed together to form a composite electrode.

FIG. 6 shows Raman spectra from three samples: 1) uncoated LiFePO₄ powder, 2) LiFePO₄ powder coated with pyrolitic carbon using currently known pyrolysis methods, and 3) LiFePO₄ powder coated with carbon using MPACVD methods according to an embodiment of the invention. The MPACVD carbon coating shows more graphite-like structure than the carbon coating produced by pyrolysis. The signal from LiFePO₄ is still present in the MPACVD carbon coated powder and there is no evidence of LiFePO₄ thermal decomposition products, such as FePₓ. This was true also in x-ray diffraction analysis (XRD) (not shown). The carbon showed a strong sp²-coordinated carbon signal, indicating graphitic structure.

LiFePO₄ active material coated with carbon deposited by MPACVD showed improved electrochemical properties relative to uncoated LiFePO₄. FIG. 7A shows a plot of cell voltage as a function of capacity for an uncoated LiFePO₄ current collector. FIG. 7B a plot of cell voltage as a function of capacity for a composite electrode containing LiFePO₄ with a MPACVD carbon coating. The measurements were made on Swagelok model cells with lithium anodes, 1 molar LiPF₆ in EC:DEC (ethyl carbonate:diethyl carbonate) 3:7 vol % electrolyte. The cells, both with and without the MPACVD carbon coating, were charged/discharged at three different rates, 5C, C/1, C/5, i.e., at currents that correspond to 5, 1, and 0.2 times, respectively, the cell nominal capacity in Ah. Comparison of FIG. 7A and FIG. 7B shows clearly that much more of the LiFePO₄ participates electrically in the current collector when the MPACVD carbon coating is present.

FIG. 7C shows electrochemical charge/discharge tests of exemplary composite cathodes. A LiNi_{1/3}Co_{1/3}Mn_{1/3}O₂ composite electrode has the following composition: 84% LiNi_{1/3}Co_{1/3}Mn_{1/3}O₂, 6% Graphite, 6% Carbon Black, 8% PVdF (polyvinylidene fluoride). Electrochemical tests were made in coin cells with a lithium-foil anode, 1 molar LiPF₆, EC:DEC 3:7 vol % electrolyte. The curves in FIG. 7C show a significant improvement of material utilization and power performance for the MPACVD carbon-coated powders (dashed curves) as compared to uncoated electrode material (solid curves) at a variety of current densities.

Without wishing to be bound by any particular theory, we believe that the improved performance is due to a larger ratio of sp²-coordinated graphite-like carbon, which exhibits better electrical conductivity than disordered or sp³-coordinated carbonaceous materials. It is highly desirable to provide a carbon deposition method which extends the benefits of highly conductive graphite films to improved electrochemical performance of composite electrodes for Li-ion batteries and for other temperature-sensitive composite electrode materials.

High-rate performance of composite electrodes has been improved by direct in situ microwave-assisted synthesis of graphitic carbon coatings on active material particles, according to some embodiments of the invention. Conductive carbon films in a composite electrode are most useful when they provide large contact area and low-resistance electronic paths from the primary active particles to the current collector. It is even more useful when the carbon layer has excellent mechanical properties, such as those of graphite, as contact between the active material particles and the carbon matrix can be maintained during long-term cell operation.

In another embodiment of the invention, a method for direct synthesis of carbon-metal catalyst thin films is described. Graphite-like carbon films decorated with metal nanoparticles can be obtained using MPACVD with organometallic precursors. The precursor can be gaseous, liquid, solid, or any combination thereof. Any organometallic compound or mixture of compounds can be used in the MPACVD process. It is useful to use an organometallic that is very low in oxygen so that a large portion of the carbon is not oxidized during processing, making it unavailable for forming the film. For example, platinum (II) acetyl-acetonate can be used to make carbon-platinum films, and copper (II) acetyl-acetonate can be used to make carbon-copper films. Carbon/metal composite layers can be produced on highly oriented pyrolytic graphite (HOPG) or other substrates during exposure to low pressure argon microwave plasma in the presence of various organic and organometallic precursors. The carbon/metal layers are conductive carbon coatings decorated with nano-dispersed metallic particles and are useful as catalysts for applications in electrochemical reactors and fuel cells.

Conventional methods for preparing platinum nanoparticles are mostly based on colloidal techniques. Some microwave heating techniques have been used wherein platinum nanoparticles were obtained by reducing H₂PtC₁₆ from aqueous solution.

In an exemplary embodiment, FIG. 8 shows a schematic diagram of an apparatus for preparing carbon-metal catalyst thin films using MPACVD. Other configurations of reactor cell for carrying out the embodiments of the invention are possible and can be designed easily by those having skill in the art. In one arrangement, a reactor cell 800 has a cylindrical vessel 810. The reactor cell 800 can be made of any material suitable for use in both vacuum and microwave environments. A substrate 820, such as highly oriented pyrolitic graphite (HOPG) is placed inside the vessel 810. An organometallic precursor 830 is also placed in the vessel 810. The precursor 830 can be positioned on top of the substrate 820 or it can be positioned near the substrate 820. In one arrangement, the organometallic precursor 830 is placed on a glass plate in proximity to the substrate 820. In yet another arrangement, a precursor line (not shown) can be provided to the reactor cell 800 to allow a continuous or semi-continuous precursor supply to the reactor cell 800. There is a vacuum valve 812 at an open end of the vessel 810. The vacuum valve opens and closes the vacuum line 816. The vacuum line 816 is also used to flush the vessel 810 with neutral gas. The apparatus shown in FIG. 8 is simpler than the device shown in FIG. 2, but either reactor cell 200, 800, or their functional equivalents can be used in the embodiments of the invention.

The reactor cell 800 is flushed with a non-reactive or neutral gas to remove traces of residual gases. In some embodiments, the neutral gas is a noble gas. In one embodiment, the neutral gas is nitrogen. The neutral gas can enter the cell 800 through the vacuum line 816. Then the reactor cell 800 can be evacuated through the same vacuum line 816. This process of filling the reactor cell 800 with neutral gas and then evacuating the reactor cell 800 can be repeated several times to ensure sufficient removal of residual gases. Finally the cell is evacuated through the vacuum line 816 to a base pressure of between about 1 mTorr and 100 mTorr, leaving the cell 800 filled with a neutral gas at low pressure. When the desired base pressure is achieved, the vacuum valve 812 is closed.

The reactor cell 800 is placed near a microwave generator. In some arrangements, the cell 200 is placed between about 5 mm and 1 m away from the microwave generator. In some arrangements, the cell 200 is placed between about 1 cm and 10 cm away from the microwave generator. The microwave generator is a standard electromagnetic generator capable of providing electromagnetic radiation within the microwave frequency range, i.e., between 300 MHz and 300 GHz. In one arrangement, frequencies between about 500 MHz and 100 GHz are used. In one arrangement, frequencies between about 750 MHz and 10 GHz are used. In one arrangement, frequencies between about 1 GHz and 5 GHz are used. The microwave generator is activated with a power input between about 10 W and 50 kW. In one arrangement, the power input is between about 100 W and 1200 W. In one arrangement, the power input was between about 600 W and 1000 W. The neutral gas in the reactor cell is excited by the microwaves to generate a plasma. The microwave radiation is continued for between about 1 second and 10 minutes. In one arrangement, the microwave radiation is continued for between about 2 seconds and 1 minute. In another arrangement, the microwave radiation is continued for between about 5 and 15 seconds. Interaction of the organic precursor(s) in the cell 800 with the low-pressure plasma and strong electromagnetic microwave radiation initiates an evaporation and pyrolysis process in the gas phase at relatively low temperatures. Plasma pyrolysis of the organometallic precursor yields films of nanometer-sized carbon particles that contain a uniform distribution of nano-sized metal particles, which precipitate on the substrate. By adjusting pyrolysis conditions such as gas pressure, microwave radiation power, exposure time, and composition of the organometallic precursor, highly graphitic carbon films with metal nanoparticles can be produced.

MPACVD methods have advantages over prior art methods for producing carbon/metal (C/M), such as carbon/platinum (C/Pt), catalyst films. The methods according to embodiments of the invention, produce C/M films directly; the C portions and the M portions of the films are produced together simultaneously. MPACVD methods are also fast, clean and inexpensive. Furthermore the Pt/M layers can be produced without stabilizers or reducing agents.

FIG. 9A shows an energy dispersive x-ray (EDX) map of a portion of a C/Pt film as shown in the scanning electron microscope (SEM) image in FIG. 9B. The bright regions are Pt-rich regions, and the dark regions are regions with essentially no Pt. FIG. 9A shows that there is a uniform distribution of small platinum particles in the carbon film.

FIG. 10A is a transmission electron microscope (TEM) image of a carbon-platinum film that shows platinum nanoparticles having sizes in the range of 2-3 nm, according to an embodiment of the invention. The graphitic structure of the carbon matrix can also be seen. FIG. 10B is an EDX spectrum taken from one of the particles in the film. The spectrum confirms that the particle is platinum. Additional peaks from the surrounding carbon matrix and from the copper TEM sample holder can also be seen. In other embodiments, metal catalyst nanoparticles can have sizes from about 1 nm to 20 nm. In yet other embodiments, metal catalyst nanoparticles can have sizes from about 1 nm to 10 nm. In yet other embodiments, metal catalyst nanoparticles can have sizes from about 1 nm to 5 nm.

The stoichiometric ratio of carbon to metal in the organic precursor determines the overall composition of the carbon-metal film. A large carbon excess in relation to the metal in the organometallic precursor results in excess of carbon and a large carbon/metal ratio in the thin films produced. When there is excess carbon, a majority of metal nanoparticles in the film are fully or partially covered by carbon, which can render the metal nanoparticles electrochemically inactive. The excess carbon can be removed from the metallic nanoparticles by using a second processing step. In the second processing step the carbon/metal film is exposed to a low-pressure microwave argon (or other neutral gas) plasma with no organic or organometallic precursors present. In one arrangement, the exposure time is between about 1 sec and 50 sec. In another arrangement, the exposure time is between about 5 sec and 15 sec.

The electrocatalytic properties of the carbon/metal nano-composite electrodes were examined with standard electrochemical tests. FIGS. 11A and 11B show cyclic voltammetry data for a C/Pt electrode prepared by MPACVD, according to an embodiment of the invention. The electrode was scanned in an aqueous 0.5 molar H₂SO₄ electrolyte and the data were taken at a voltage scan rate of 500 mV/sec. FIG. 11A shows current density (mA/cm²) as a function of potential vs. saturated calomel electrode (SCE) for a C/Pt film on a HOPG substrate. This cyclic voltammogram displays electrocatalytic characteristics typical for platinum. However, the current density per centimeter square of the geometric area is about 100 times larger for the C/Pt electrode as compared to a solid Pt electrode (FIG. 11B). These data indicate an exceptionally high level of dispersion of platinum catalyst on a conductive carbon support.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a graph of electronic resistance as a function of pyrolysis temperature for thin films of pyrolized photoresist.

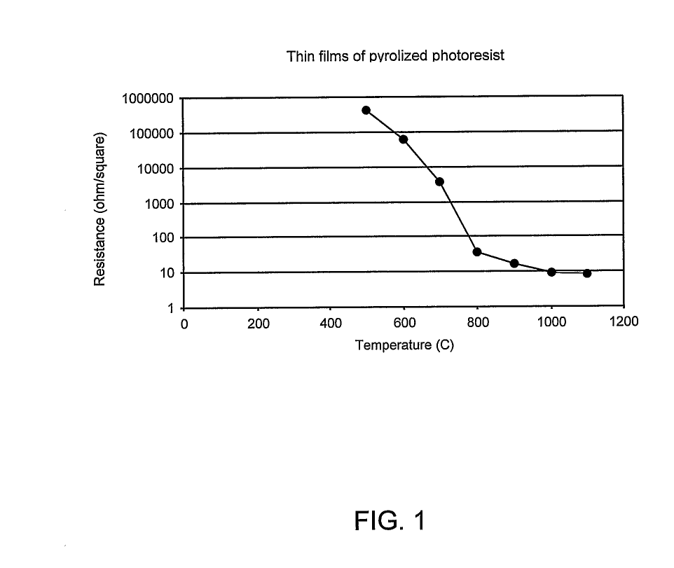

FIG. 2 shows a schematic cross-section view of a reactor cell 200 that can be used for MPACVD, according to an embodiment of the invention.

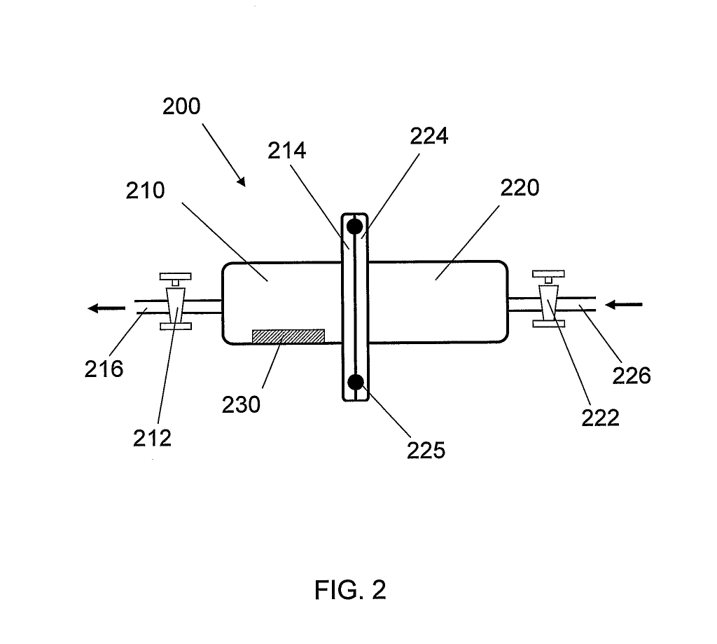

FIG. 3 is a graph showing current-voltage characteristics, as measured by four-point probe technique, of carbon films made using the methods described herein.

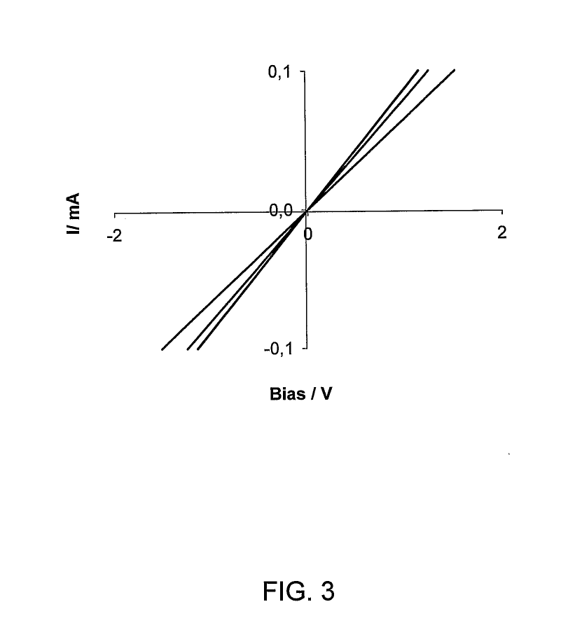

FIG. 4 shows Raman spectra of four different carbon films made using the methods described herein.

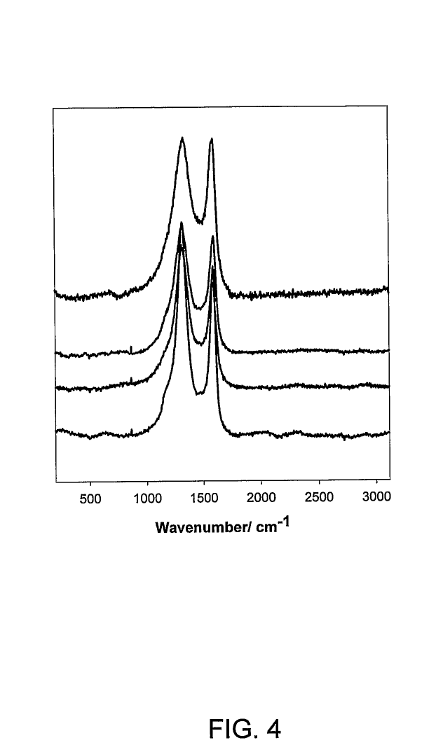

FIG. 5 is a table showing resistivity values of carbon films for various ratios of sp³- to sp²-coordinated carbon.

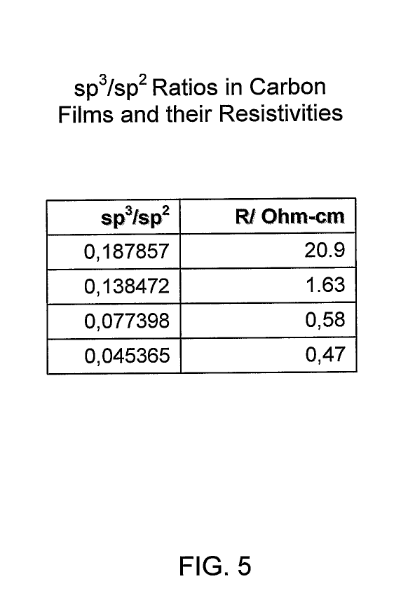

FIG. 6 shows Raman spectra of LiFePO₄ powder taken on uncoated powder, on pyrolitic carbon-coated powder made using current pyrolysis methods, and on MPACVD carbon coated powder.

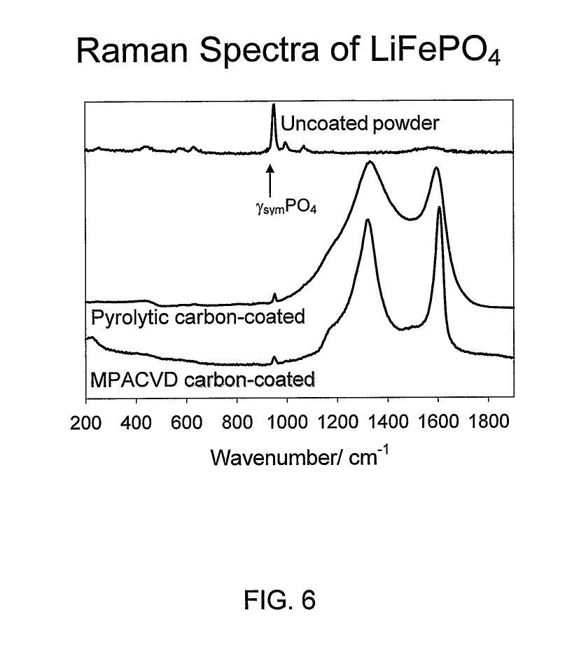

FIGS. 7A and 7B show plots of cell voltage as a function of capacity for uncoated LiFePO₄ and for LiFePO₄ with a MPACVD carbon coating, respectively.

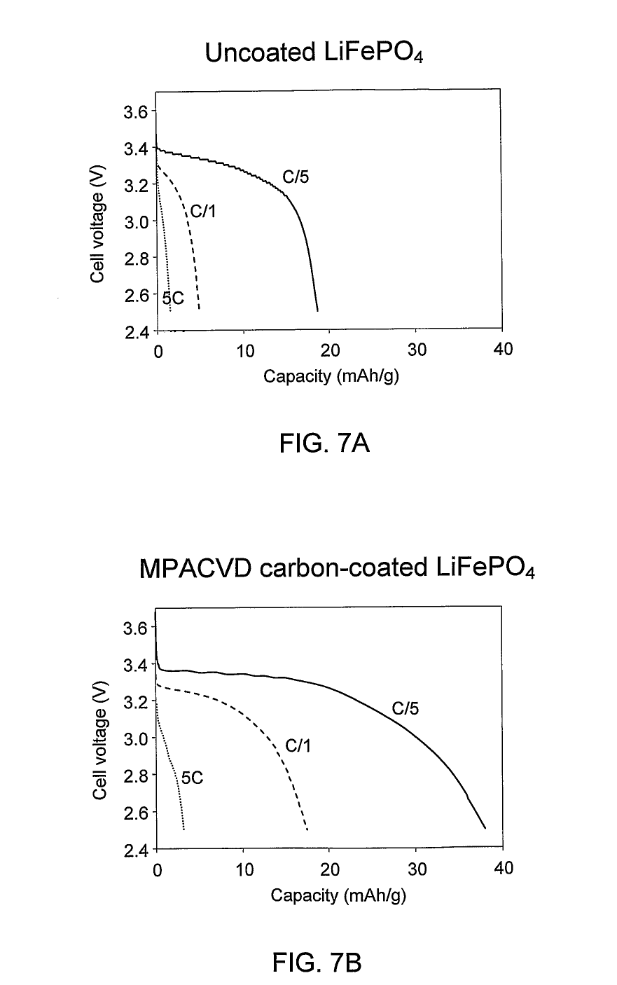

FIG. 7C shows data from electrochemical charge/discharge tests on exemplary LiNi_{1/3}Co_{1/3}Mn_{1/3}O₂ composite cathodes with and without MPACVD carbon coating.

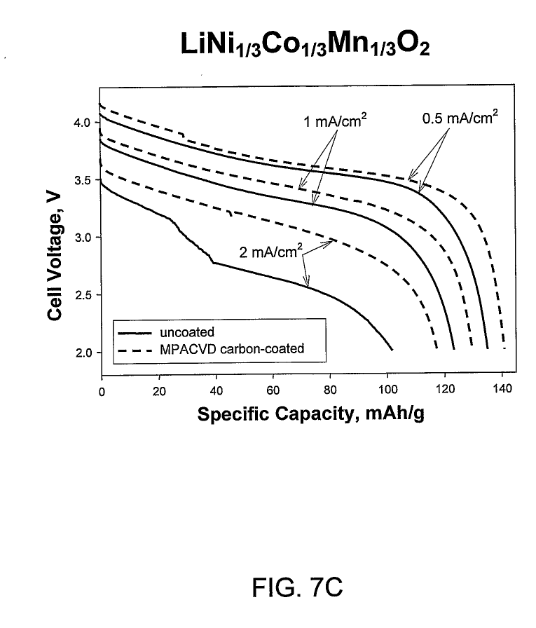

FIG. 8 is a schematic diagram of an apparatus for preparing carbon-metal catalyst thin films.

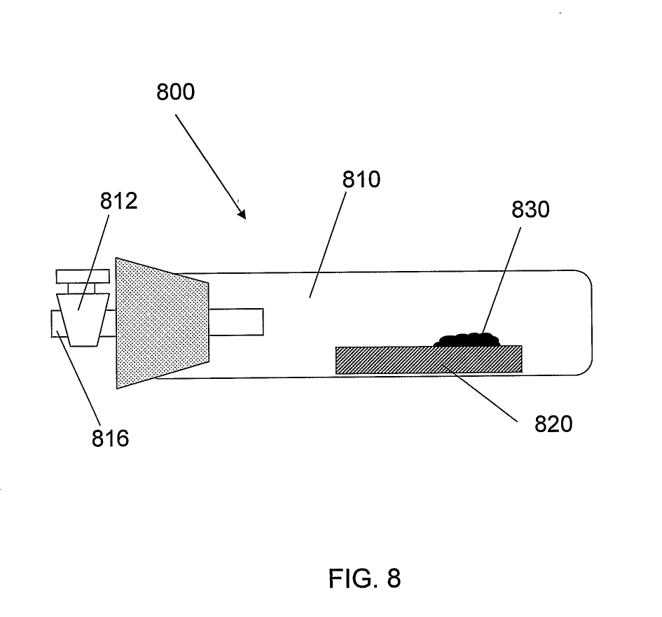

FIG. 9A shows an EDX map of a portion of a carbon/platinum film as shown in the transmission electron microscope (TEM) image in FIG. 9B.

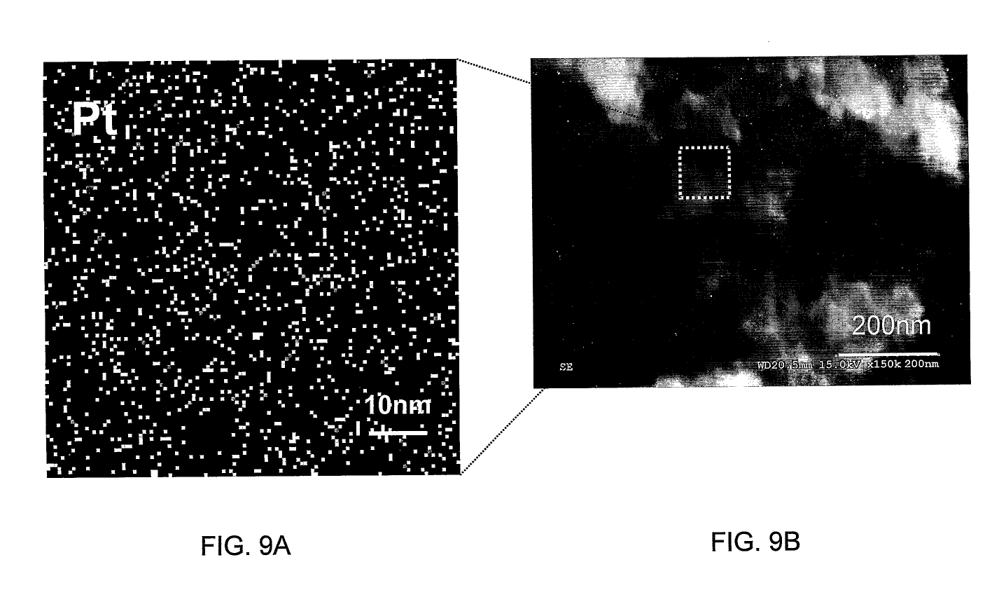

FIG. 10A is a transmission electron microscope (TEM) image of a carbon-platinum film. FIG. 10B is an EDX spectrum taken from one of the particles in the film.

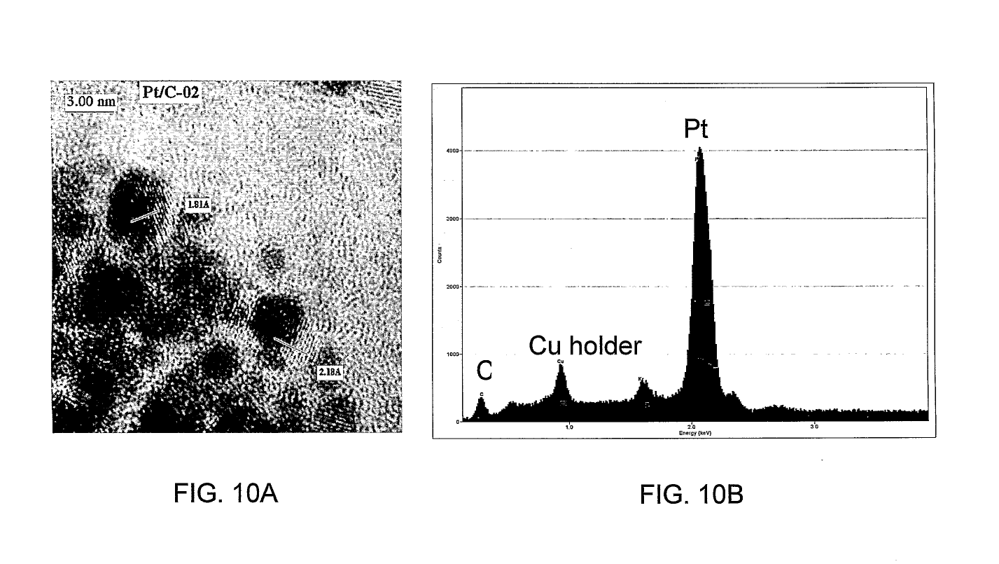

FIG. 11A shows a cyclic voltammogram for a C/Pt composite electrode that was prepared using MPACVD. FIG. 11B shows a cyclic voltammogram for a Pt solid electrode.

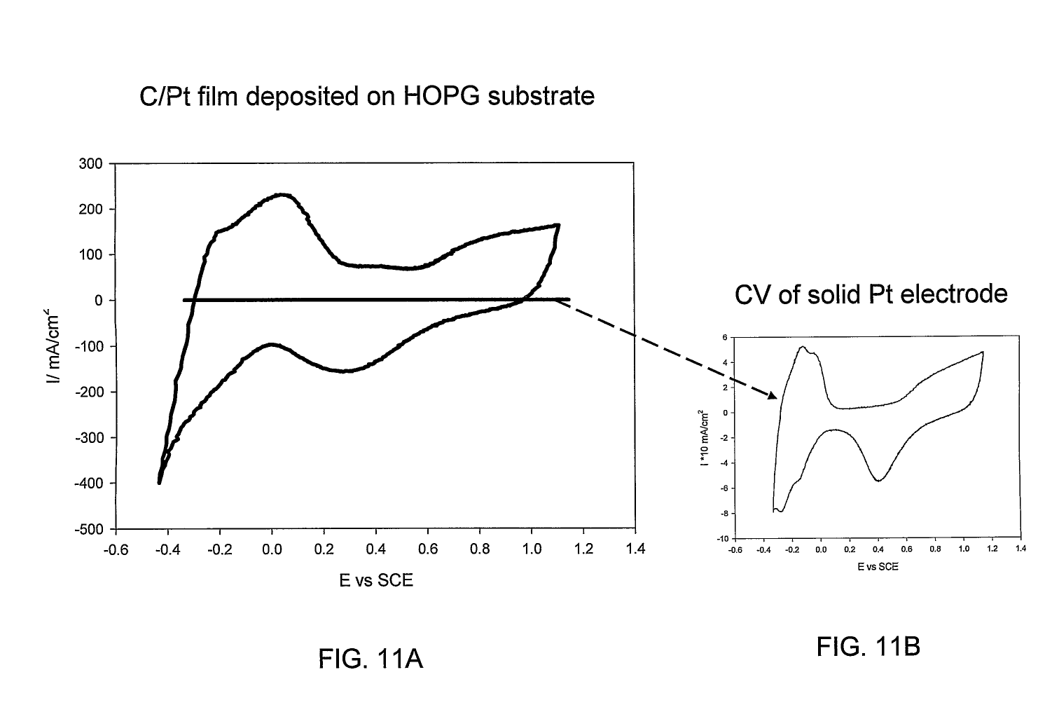

### INDUSTRIAL APPLICABILITY

Composite electrodes, as are used in primary and secondary batteries and for fuel cells work more efficiently when there is a low resistance electronic path between the active material and the current collector. Carbon is the material most often used to provide this low resistance electrical path. With current pyrolytic methods, the quality of the carbon that can be deposited onto temperature-sensitive active electrode materials is poor. Carbon deposited by MPACVD methods is done at much lower temperatures and with much higher quality than carbon deposited by pyrolytic methods. MPACVD carbon is highly graphitic and has better electrical conductivity than pyrolytic carbon currently used in composite electrodes. In addition, MPACVD carbon has excellent mechanical properties, such as those of graphite, so that contact between active material particles and the carbon matrix in a composite electrode can be maintained during long-term cell operation. It is very useful to provide a carbon deposition method which extends the benefits of highly conductive graphite films to improved electrochemical performance of composite electrodes for Li-ion batteries and for other temperature-sensitive composite electrode materials. Graphitic carbon supports produced by MPACVD has better corrosion resistance in the fuel cell environment than standard carbon black supports used in the present state-of-the-art fuel cell composite electrodes.

MPACVD methods have advantages over prior art methods also for producing carbon/metal (C/M), e.g., C/Pt, catalyst films. The C/M films can be produced directly; the C portions and the M portions of the films are produced together simultaneously. MPACVD methods are also fast, clean and inexpensive. Electronically conductive graphitic carbon films decorated with uniformly distributed ultra-fine catalyst particles can be formed on any type of substrate. Furthermore the C/M films can be produced without stabilizers or reducing agents.

1. A method for forming a graphitic carbon film, comprising the steps of:
providing a reactor cell;
placing a substrate in the reactor cell;
providing a source of carbon precursor material to the reactor cell;
filling the reactor cell with a neutral gas at a pressure between about 1 mTorr and 100 mTorr; and
irradiating the reactor cell with microwave radiation,
thereby producing a plasma in the reactor cell and forming the carbon film.

2. The method of claim 1 wherein providing a source of carbon precursor material comprises coating at least a portion of the substrate with the carbon precursor material before placing the substrate in the reactor cell.

3. The method of claim 1 wherein providing a source of carbon precursor material comprises placing the carbon precursor material in the reactor cell in proximity to the substrate.

4. The method of claim 1 wherein providing a source of carbon precursor material comprises providing a carbon precursor material line to the reactor cell and supplying the carbon precursor material to the reactor cell through the line.

5. The method of claim 1, further comprising the step of flushing the reactor cell with the neutral gas one or more times before the filling step.

6. The method of claim 1 wherein the substrate reaches a temperature no higher than 800° C.

7. The method of claim 1 wherein the substrate reaches a temperature no higher than 500° C.

8. The method of claim 1 wherein the substrate reaches a temperature no higher than 200° C.

9. The method of claim 1 wherein the reactor cell comprises glass.

10. The method of claim 1 wherein the substrate comprises a continuous solid or a solid in the form of a powder.

11. The method of claim 1 wherein the carbon precursor comprises an organic material that yields CₓH_{y} radicals upon interaction with plasma wherein x/y is between about 1 and 3.

12. The method of claim 11 wherein x/y is between about 2 and 3.

13. The method of claim 1 wherein the carbon precursor comprises a material selected from the group consisting of polystyrene, naphthalene, anthracene.

14. The method of claim 1 wherein the carbon precursor comprises a material selected from the group consisting of sugar and tar.

15. The method of claim 1 wherein the neutral gas is selected from the group consisting of noble gases and nitrogen.

16. The method of claim 1 wherein the microwave radiation has a frequency between about 750 MHz and 10 GHz.

17. The method of claim 1 wherein the microwave radiation has a frequency between about 1 GHz and 5 GHz.

18. The method of claim 1 wherein the microwave radiation is generated with a power input between about 10 W and 50 kW.

19. The method of claim 1 wherein the microwave radiation is generated with a power input between about 60 W and 1000 W.

20. The method of claim 1 wherein the irradiating step continues for between about 1 second and 1 minute.

21. The method of claim 1 wherein the irradiating step continues for between about 5 seconds and 15 seconds.

22. A method of forming a catalyst film, comprising the steps of:
providing a reactor cell;
placing a substrate in the reactor cell;
providing a source of organometallic precursor material to the reactor cell;
filling the reactor cell with a neutral gas at a pressure between about 1 mTorr and 100 mTorr; and
irradiating the reactor cell with microwave radiation,
thereby producing a plasma in the reactor cell and forming the catalyst film.

23. The method of claim 22 wherein the organometallic precursor material is selected from the group consisting of platinum (II) acetyl-acetonate and copper (II) acetyl-acetonate.

24. The method of claim 22 wherein the catalyst film comprises a graphitic carbon film decorated with uniformly distributed metal nanoparticles.

25. The method of claim 24 wherein the metal nanoparticles have sizes between about 1 and 20 nm.

26. The method of claim 25 wherein the metal nanoparticles have sizes between about 1 and 5 nm.

27. A method of forming a composite electrode, comprising the steps of:
providing a reactor cell;
placing active electrode material particles in the reactor cell;
providing a source of carbon precursor material to the reactor cell;
filling the reactor cell with a neutral gas at a pressure between about 1 mTorr and 100 mTorr; and
irradiating the reactor cell with microwave radiation to form carbon-coated active electrode material particles;
removing the carbon-coated active electrode material particles from the reactor cell; and
pressing the carbon-coated active electrode material particles together to form a composite electrode.

28. The method of claim 27 wherein the active electrode material particles are selected from the group consisting of LiFePO₄, LiNi_{1/3}Co_{1/3}Mn_{1/3}O₂, LiCoO₂, LiNiO₂, LiNi_{0.8}CO_{0.2}O₂, and LiNi_{0.8}Cu_{0.15}Al_{0.05}O₂.
